(19) United States
(12) Patent Application Publication
(10) Pub. No.: US 2026/0059705 A1
(43) Pub. Date: Feb. 26, 2026

(54) COOLING ASSEMBLY BASED ON CONTACTLESS DRIVE STRUCTURE

(71) Applicant: Garsendee Technology Co., Ltd, Dongguan (CN)

(72) Inventors: Hongming ZHU, Yueqing (CN); Zhicheng LIN, Guangzhou (CN)

(73) Assignee: Garsendee Technology Co., Ltd, Dongguan (CN)

(21) Appl. No.: 19/373,625

(22) Filed: Oct. 29, 2025

Related U.S. Application Data
(63) Continuation-in-part of application No. 18/884,390, filed on Sep. 13, 2024.

(30) Foreign Application Priority Data
Aug. 21, 2024 (CN) 202422037070.6
Sep. 23, 2025 (CN) 202522061862.1

(51) Int. Cl. H05K 7/20; G06F 1/20

(52) U.S. Cl. CPC H05K 7/20272; G06F 1/20; H05K 7/20263

(57) ABSTRACT

A cooling assembly based on a contactless drive structure includes a housing and a drive device. The housing is provided with a cavity inside, and an impeller is rotatably disposed in the cavity; the housing is further provided with a fluid inlet and a fluid outlet, and both the fluid inlet and the fluid outlet are in communication with the cavity. The drive device includes a stator and a rotor, a pump seat is detachably disposed on an upper portion of the housing, the stator is disposed on the pump seat, the rotor is directly or indirectly connected to the impeller, and magnetic fields of the rotor and the stator are axially or radially tangent to each other; the drive device is configured to drive the impeller to rotate via the stator and the rotor.

### CROSS-REFERENCE TO RELATED APPLICATIONS

The present application is a continuation-in-part of U.S. patent application Ser. No. 18/884,390, filed Sep. 13, 2024, which claims priority to Chinese Patent Application No. 202422037070.6, filed on Aug. 21, 2024. The present application also claims priority to Chinese Patent Application No. 202522061862.1, filed on Sep. 23, 2025. All of the aforementioned applications are incorporated herein by reference in their entireties.

### TECHNICAL FIELD

The present disclosure relates to the field of application, and particularly relates to a cooling assembly based on a contactless drive structure.

### BACKGROUND

Computer water cooling refers to a cooling system used for lowering the temperature of heat-generating components in a computer. It utilizes a liquid with a high specific heat capacity (e.g., water) as a medium to help transfer heat away from internal parts. Computer water cooling generally offers the following advantages: small temperature fluctuations under circulating cooling, significant temperature control for the cooled components, and stable, reliable long-term operation.

In existing integrated pump designs, a rotor is typically disposed within an internal cavity of the pump and is connected to an impeller, while a stator is disposed on the pump housing. To enable the stator to drive the impeller to rotate via the rotor, magnetic flux directions of the rotor and the stator must be the same, and magnetic fields of the rotor and the stator must be tangential. This necessitates specific structures within the housing and the internal cavity for mounting the stator and the rotor, allowing for the use of only either an axial flux motor or a radial flux motor, resulting in poor versatility.

Certainly, separate structures for the pump and the water chamber also exist, but such structures increase the volume of the cooling system.

### SUMMARY

A primary objective of the present disclosure is to provide a cooling assembly based on a contactless drive structure.

To achieve the above objective, the present disclosure provides a cooling assembly based on a contactless drive structure, including:
a housing, wherein the housing is provided with a cavity inside, and an impeller is rotatably disposed in the cavity; the housing is provided with a fluid inlet and a fluid outlet, and both the fluid inlet and the fluid outlet are in communication with the cavity;
a drive device, wherein the drive device includes a stator and a rotor, a pump seat is detachably disposed on an upper portion of the housing, the stator is disposed on the pump seat, the rotor is directly or indirectly connected to the impeller, and magnetic fields of the rotor and the stator are axially or radially tangent to each other;
the drive device is configured to drive the impeller to rotate via the stator and the rotor, so as to drive fluid to enter the cavity from the fluid inlet, and then be discharged from the cavity via the fluid outlet; and
a bottom of the housing is provided with a heat conduction surface.

The present disclosure offers the following four advantages.

Firstly, the housing of the present disclosure is a universal part. A pump seat is disposed on the housing. An axial drive device or a radial drive device can be selected as needed by matching the rotor on the impeller with the stator on the pump seat, thereby enabling flexible production.

Secondly, when the axial drive device is installed, the pump body has a flattened shape and is more lightweight.

Thirdly, when the radial drive device is installed, thermal management is straightforward, making the assembly suitable for continuous high-load operation.

Lastly, a flow guide channel is disposed in the water chamber of the present disclosure, configured to guide water delivered from an impeller chamber to a heat exchange region for sufficient heat exchange with a heat conduction surface, thereby improving the cooling effect of the cooling assembly.

### BRIEF DESCRIPTION OF THE DRAWINGS

FIG. 1 is a perspective view of a cooling assembly according to an embodiment of the present disclosure, where a drive device is an axial flux motor.

FIG. 2 is a cross-sectional view of the cooling assembly according to the embodiment of the present disclosure, where the drive device is the axial flux motor.

FIG. 3 is a perspective view of the cooling assembly from another perspective according to the embodiment of the present disclosure, where the drive device is the axial flux motor.

FIG. 4 is an exploded view of the cooling assembly according to the embodiment of the present disclosure, where the drive device is the axial flux motor.

FIG. 5 is an enlarged view of portion A in FIG. 4.

FIG. 6 is an exploded view of the cooling assembly from another perspective according to the embodiment of the present disclosure, where the drive device is the axial flux motor.

FIG. 7 is a schematic structural view of a stator and a rotor according to the embodiment of the present disclosure, where the drive device is the axial flux motor.

FIG. 8 is another cross-sectional view of the cooling assembly according to the embodiment of the present disclosure, where the drive device is the axial flux motor.

FIG. 9 is a perspective view of the cooling assembly according to the embodiment of the present disclosure, where the drive device is a radial flux motor.

FIG. 10 is a cross-sectional view of the cooling assembly according to the embodiment of the present disclosure, where the drive device is the radial flux motor.

FIG. 11 is a perspective view of the cooling assembly from another perspective according to the embodiment of the present disclosure, where the drive device is the radial flux motor.

FIG. 12 is an exploded view of the cooling assembly according to the embodiment of the present disclosure, where the drive device is the radial flux motor.

FIG. 13 is an exploded view of the cooling assembly from another perspective according to the embodiment of the present disclosure, where the drive device is the radial flux motor.

FIG. 14 is another cross-sectional view of the cooling assembly according to the embodiment of the present disclosure, where the drive device is the radial flux motor.

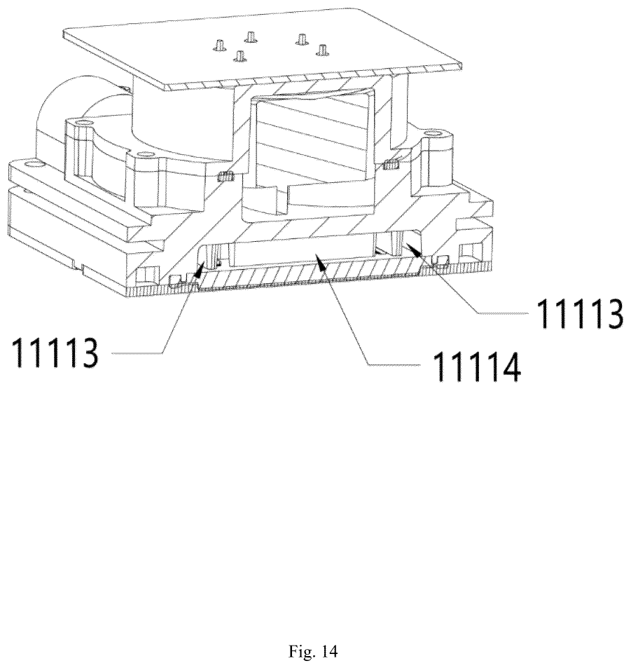

### DETAILED DESCRIPTION OF THE EMBODIMENTS

The technical solutions in the embodiments of the present disclosure will be clearly and completely described below with reference to the accompanying drawings. Obviously, the described embodiments are only a part of the embodiments of the present disclosure, rather than all of the embodiments. Based on the embodiments in the present disclosure, all other embodiments obtained by persons of ordinary skill in the art without creative effort shall fall within the protection scope of the present disclosure.

It should be noted that if there are directional indications (such as up, down, left, right, front, back, top, bottom, inside, outside, vertical, transverse, longitudinal, counterclockwise, clockwise, circumferential, radial, axial.. .), this directional indication is only used to explain the relative positional relationship, movement, etc. between the components in a specific posture (as shown in the accompanying drawings). If the specific posture changes, the directional indication also changes accordingly.

In addition, if there are descriptions involving “first” or “second” etc. in the embodiments of the present disclosure, the descriptions of “first” or “second” etc. are only for descriptive purposes and cannot be understood as instructions or implying its relative importance or implicitly specifying the quantity of the technical feature indicated. Therefore, features defined as “first” and “second” may explicitly or implicitly include at least one of these features. In addition, the technical solutions in various embodiments may be combined with each other, provided that such combinations are realizable by those skilled in the art. Where the combination of technical solutions is contradictory or unfeasible, it shall be deemed that such a combination does not exist and is not within the scope of protection required by the present disclosure.

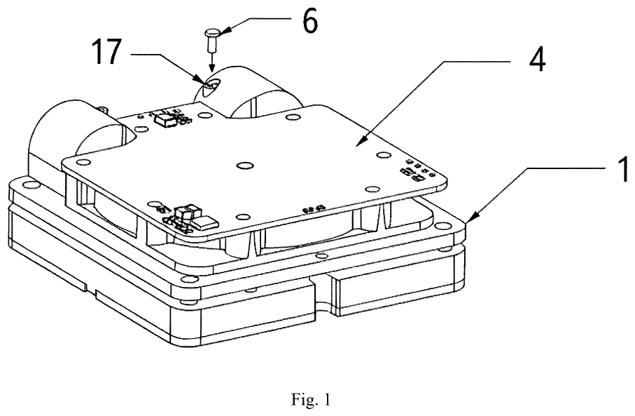

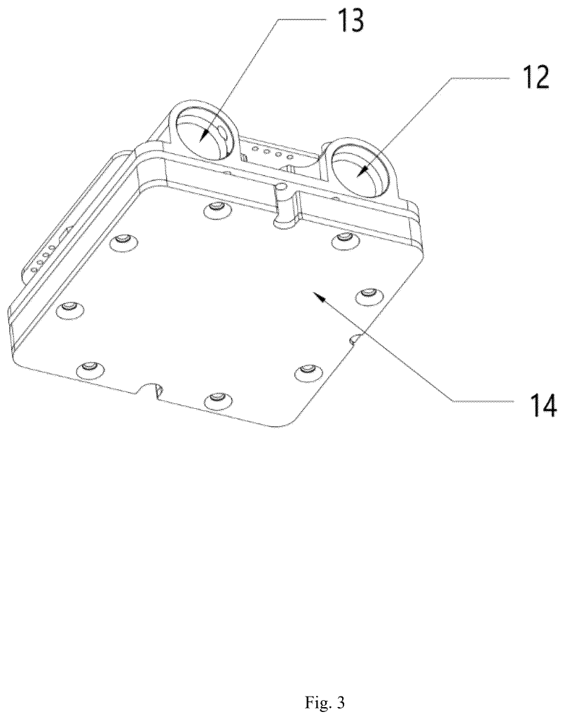

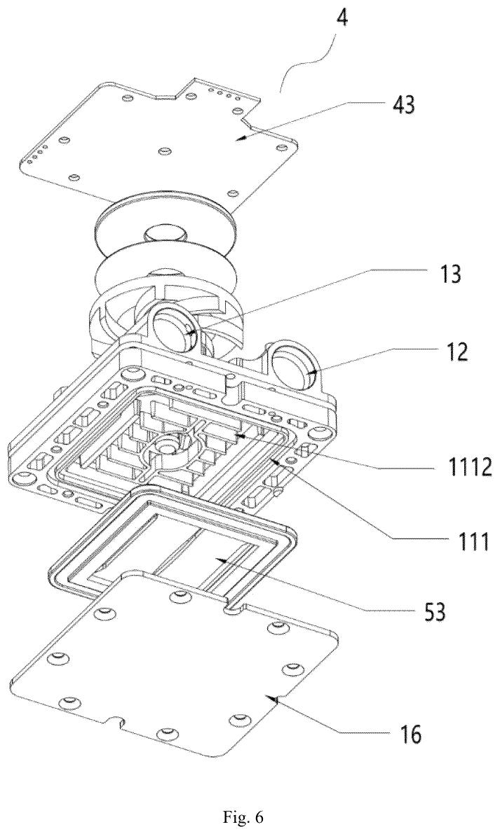

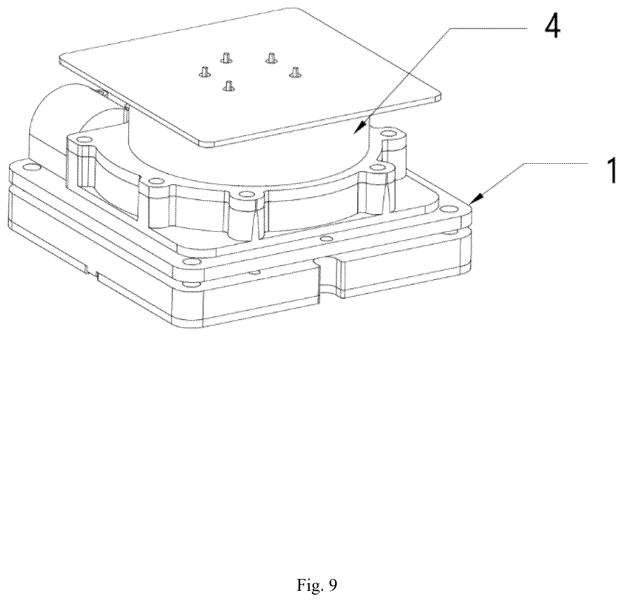

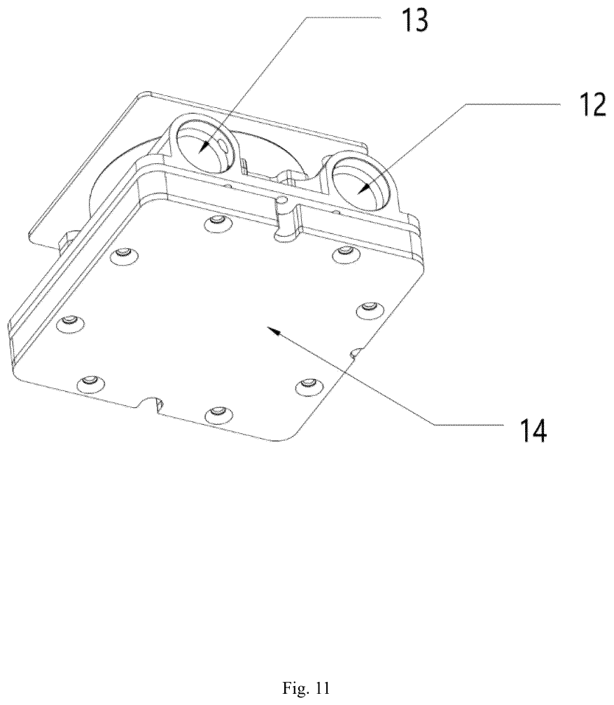

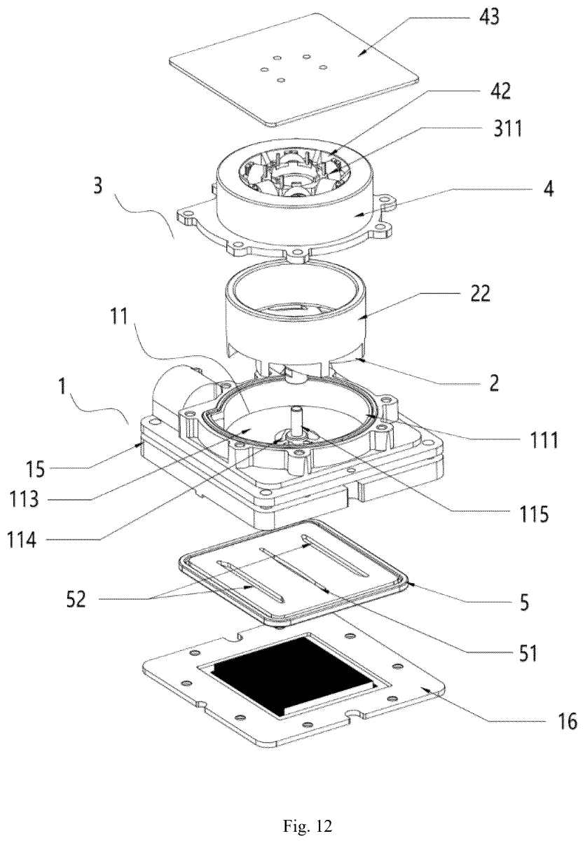

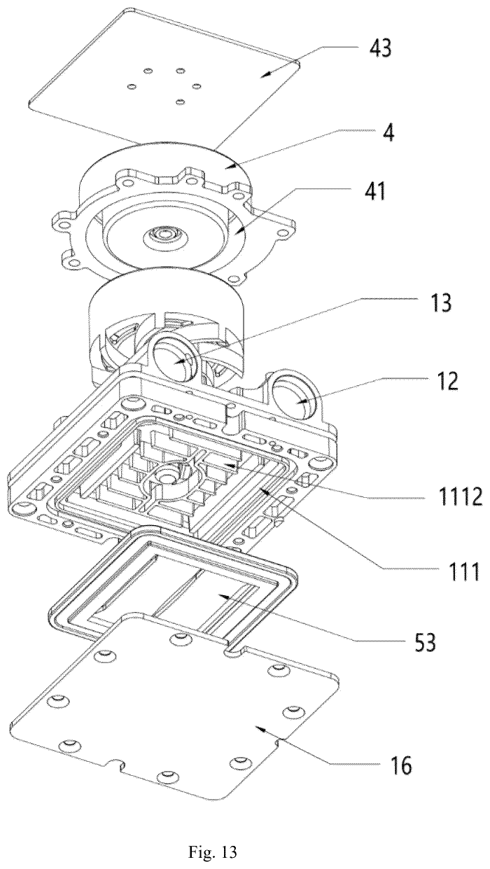

As shown in FIGS. 1, 2, 3, 4, 6, 8, 9, 10, 11, 12, and 13, a cooling assembly based on a contactless drive structure includes:
a housing 1, wherein the housing 1 is provided with a cavity 11 inside, and an impeller 2 is rotatably disposed in the cavity 11;
the housing 1 is provided with a fluid inlet 12 and a fluid outlet 13, and both the fluid inlet 12 and the fluid outlet 13 are in communication with the cavity 11;
a drive device 3, wherein the drive device 3 includes a stator 31 and a rotor 32, a pump seat 4 is detachably disposed on an upper portion of the housing 1, the stator 31 is disposed on the pump seat 4, the rotor 32 is directly or indirectly connected to the impeller 2, and magnetic fields of the rotor 32 and the stator 31 are axially or radially tangent to each other;
the drive device 3 is configured to drive the impeller 2 to rotate via the stator 31 and the rotor 32, so as to drive fluid to enter the cavity 11 from the fluid inlet 12, and then be discharged from the cavity 11 via the fluid outlet 13; and
a bottom of the housing 1 is provided with a heat conduction surface 14.

Preferably, a rotating shaft 115 is rotatably disposed in the cavity 11, and the impeller 2 is disposed on the rotating shaft 115.

The housing 1 is configured to be directly mounted on a heat-generating component (for example: a graphics card, a Central Processing Unit (CPU)), with the heat conduction surface 14 attached to the heat-generating component.

This embodiment is based on any of the foregoing embodiments to illustrate the specific structure of the present disclosure when the drive device 3 is an axial flux motor.

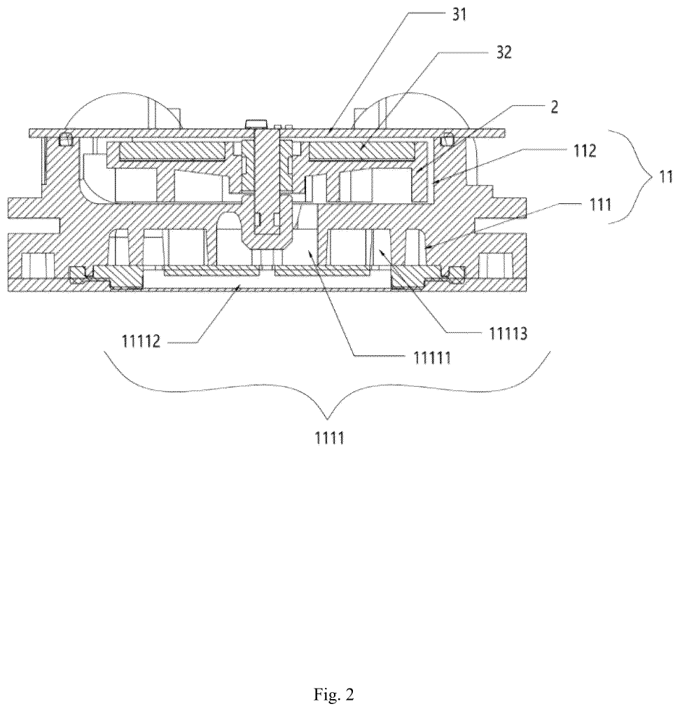

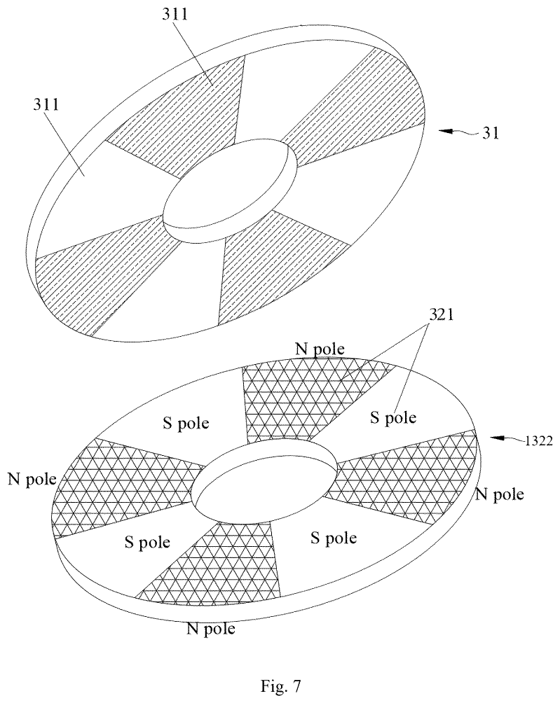

As shown in FIGS. 2, 4, 6, and 7, in this embodiment, a disc 21 extending in a radial direction of the impeller 2 is disposed on an upper portion of the impeller 2; an annular mounting groove 211 is formed in the disc 21; and a rotor 32 is mounted in the annular mounting groove 211. Specifically, the rotor 32 includes a plurality of permanent magnets 321, the stator 31 includes a plurality of induction coils 311, the permanent magnets 321 are disposed on the disc 21, both the permanent magnets 321 and the induction coils 311 are distributed along a circumferential direction of the disc 21, and magnetic flux directions of the induction coils 311 and the permanent magnets 321 are along an axial direction of the impeller 2.

A shape of each of the permanent magnets 321 is sector-shaped; each of the permanent magnets 321 includes an N-pole and an S-pole; the N-poles and the S-poles are distributed at intervals along the circumferential direction of the disc 21. A pump base 4 is a PCB 43 disposed on a top of the housing 1; the induction coils 311 are disposed on the PCB 43; the PCB 43 is provided with a controller; all the induction coils 311 are electrically connected to the controller.

Preferably, the rotor 32 and the disc 21 are integrally formed. An injection molding process can be employed for the integral forming, to fix the rotor 32 within the disc 21.

Preferably, a projected area of the stator 31 and a projected area of the rotor 32 are identical.

This embodiment is based on any of the foregoing embodiments to illustrate the specific structure of the present disclosure when the drive device 3 is a radial flux motor.

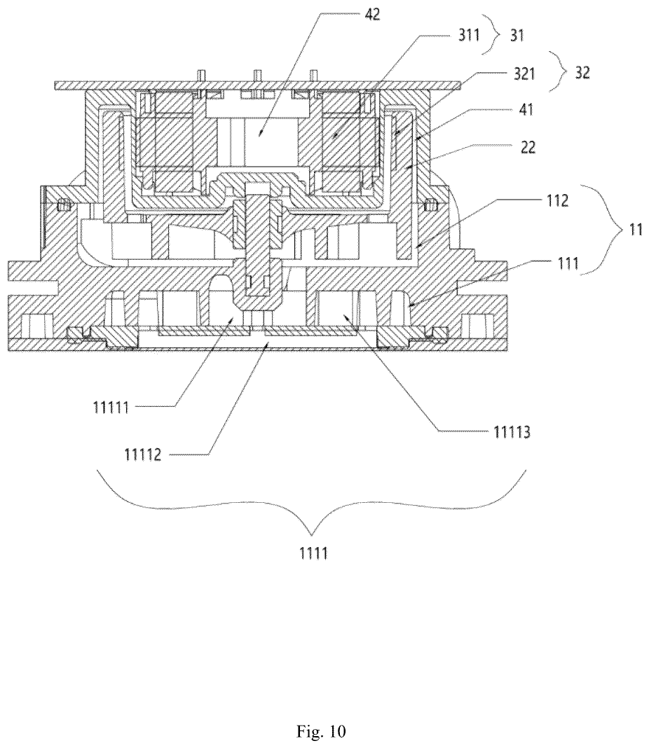

As shown in FIGS. 10, 12, and 13, in this embodiment, a cylinder 22 extending in the axial direction of the impeller 2 is disposed on the impeller 2. Specifically, the rotor 32 includes a plurality of permanent magnets 321, the stator 31 includes a plurality of induction coils 311, the permanent magnets 321 are disposed on the cylinder 22, both the permanent magnets 321 and the induction coils 311 are distributed along a circumferential direction of the cylinder 22, and magnetic flux directions of the induction coils 311 are along a radial direction of the impeller 2.

The pump seat 4 is disposed on the top of the housing 1; a bottom of the pump seat 4 is provided with an annular groove 41; the annular groove 41 is in communication with the cavity 11; and the cylinder 22 is located in the annular groove. A top of the pump seat 4 is provided with a mounting groove 42 recessed downward, the mounting groove 42 is located in the annular groove 41, and the stator 31 is disposed in the mounting groove 42.

Furthermore, in this embodiment, a PCB 43 is disposed on the top of the pump seat 4; the PCB 43 is electrically connected to all the induction coils 311; the PCB 43 is provided with a controller; all the induction coils 311 are electrically connected to the controller.

This embodiment is based on any of the foregoing embodiments to illustrate the specific structure of the cavity 11 according to the present disclosure.

As shown in FIGS. 2, 4, 6, 10, 12, and 13, in this embodiment, the cavity 11 includes a water chamber 111 and an impeller chamber 112; the impeller chamber 112 is located above the water chamber 111; a partition plate 113 is disposed between the water chamber 111 and the impeller chamber 112; a plurality of first through holes 114 are provided on the partition plate 113; the first through holes 114 are in communication with water chamber 111 and the impeller chamber 112; the impeller 2 is located in the impeller chamber 112; the fluid inlet 12 is in communication with the impeller chamber 112; and the fluid outlet 13 is in communication with the water chamber 111.

A flow guide channel 1111 is disposed in the water chamber 111; the flow guide channel 1111 is in communication with the first through holes 114, the heat conduction surface 14, and the fluid outlet 13; and when the impeller 2 rotates, the impeller 2 is configured to drive fluid to pass sequentially through the fluid inlet 12, the impeller chamber 112, the flow guide channel 1111, and the fluid outlet 13.

The flow guide channel 1111 includes a first flow guide channel 11111, a heat exchange region 11112, and a second flow guide channel 11113; the heat exchange region 11112 is located at a lower portion of the water chamber 111; the heat exchange region 11112 is in communication with the heat conduction surface 14; the first flow guide channel 11111 is in communication with both the first through holes 114 and the heat exchange region 11112; and the second flow guide channel 11113 is in communication with both the heat exchange region 11112 and the fluid outlet 13.

The water chamber 111 is provided with a flow guide base 5 inside; the flow guide base 5 is provided with a second through hole 51 and a third through hole 52; both the second through hole 51 and the third through hole 52 penetrate through the flow guide base 5 vertically; a bottom of the flow guide base 5 is provided with a recess 53; an inner area of the recess 53 forms the heat exchange region 11112; and both the second through hole 51 and the third through hole 52 are in communication with the recess 53.

A top of the water chamber 111 is provided with a plurality of first flow guide ribs 1112; the first flow guide ribs 1112 and the first through holes 114 form the first flow guide channel 11111; and the third through hole 52 and the first flow guide ribs 1112 form the second flow guide channel 11113.

This embodiment is based on any of the foregoing embodiments to illustrate the specific structure of the cavity 11 according to the present disclosure.

In this embodiment, the cavity 11 includes a water chamber 111 and an impeller chamber 112, the impeller chamber 112 is located above the water chamber 111, a partition plate 113 is disposed between the water chamber 111 and the impeller chamber 112, a plurality of first through holes 114 are provided on the partition plate 113, the first through holes 114 are in communication with water chamber 111 and the impeller chamber 112, the impeller 2 is located in the impeller chamber 112, the fluid inlet 12 is in communication with the impeller chamber 112, and the fluid outlet 13 is in communication with the water chamber 111.

A flow guide channel 1111 is disposed in the water chamber 111; the flow guide channel 1111 is in communication with the first through holes 114, the heat conduction surface 14, and the fluid outlet 13; and when the impeller 2 rotates, the impeller 2 is configured to drive fluid to pass sequentially through the fluid inlet 12, the impeller chamber 112, the flow guide channel 1111, and the fluid outlet 13.

The flow guide channel 1111 includes a first flow guide channel 11111, a heat exchange region 11112, and a second flow guide channel 11113; the heat exchange region 11112 is located at a lower portion of the water chamber 111; the heat exchange region 11112 is in communication with the heat conduction surface 14; the first flow guide channel 11111 is in communication with both the first through holes 114 and the heat exchange region 11112; and the second flow guide channel 11113 is in communication with both the heat exchange region 11112 and the fluid outlet 13.

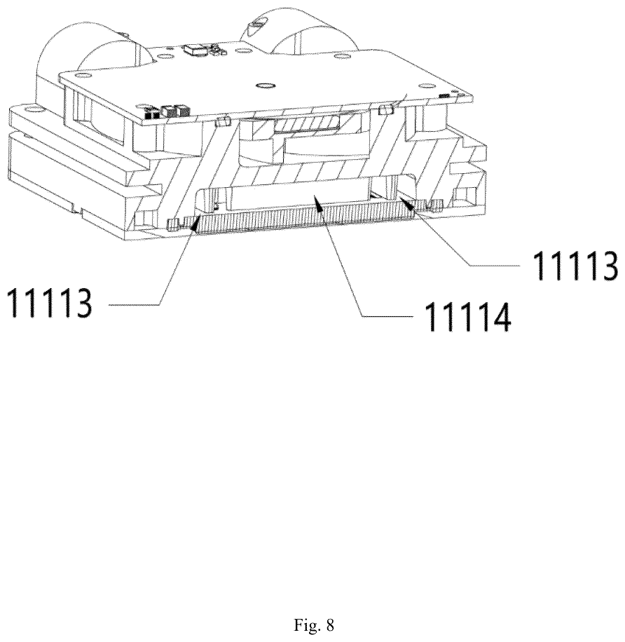

As shown in FIG. 8, and 14, in this embodiment, the second flow guide channel 11113 is disposed on each of both sides of the first flow guide channel 11111; the two second flow guide channels 11113 are connected via a connection channel 11114; and one of the second flow guide channels 11113 is in communication with the fluid outlet 13.

The water chamber 111 is provided with a flow guide base 5 inside; the flow guide base 5 is provided with a second through hole 51 and a third through hole 52; both the second through hole 51 and the third through hole 52 penetrate through the flow guide base 5 vertically; the third through hole 52 is disposed on each of both sides of the second through hole 51; a bottom of the flow guide base 5 is provided with a recess 53; an inner area of the recess 53 forms the heat exchange region 11112; and both the second through hole 51 and the third through hole 52 are in communication with the recess 53.

A top of the water chamber 111 is provided with a plurality of first flow guide ribs 1112; the first flow guide ribs 1112 and the second through hole 51 form the first flow guide channel 11111; the two third through holes 52 and the first flow guide ribs 1112 form the two second flow guide channels 11113; and the first flow guide ribs 1112 further form the connection channel 11114.

In this embodiment, two second flow guide channels 11113 are arranged. The two second flow guide channels 11113 are distributed on two sides of the first flow guide channel 11111. When fluid enters the heat exchange region from the first flow guide channel, the fluid enters the second flow guide channels 11113 from two sides of the heat exchange region, then converges through a connection channel, and is subsequently discharged together from the fluid outlet 13. This configuration further optimizes a flow path of the fluid, enabling the fluid to flow fully within the heat exchange region to absorb heat transmitted from the heat conduction surface 14.

This embodiment is based on any of the foregoing embodiments. A plurality of second flow guide ribs 1113 are disposed on a bottom of the water chamber 111. Heat exchange channels 1114 are formed between the second flow guide ribs 1113. The heat exchange channels 1114 are configured to improve heat exchange efficiency.

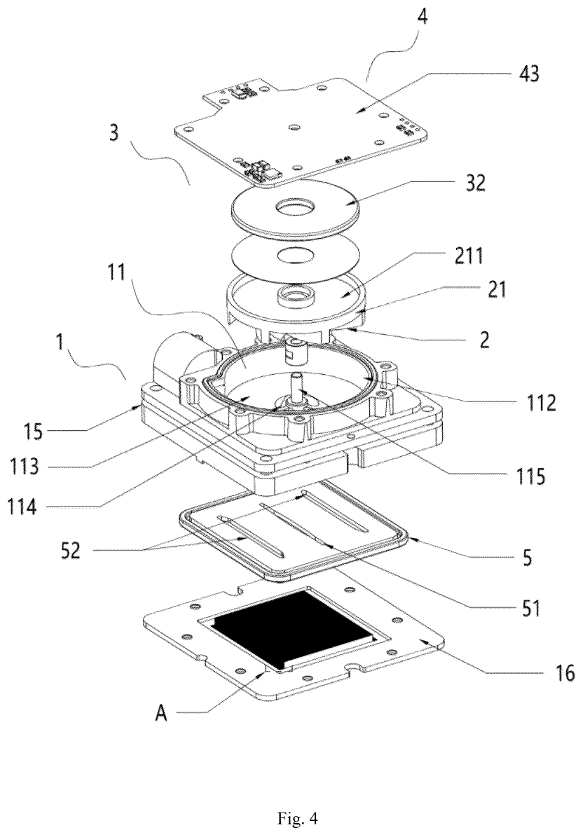

As shown in FIGS. 4, 6, 12, and 13, this embodiment is based on any of the foregoing embodiments. The housing 1 includes an upper shell 15 and a bottom cover 16; the cavity 11 is provided at a bottom of the upper shell 15; the bottom cover 16 is configured to close the bottom of the upper shell 15; and the pump seat 4 is mounted on a top of the upper shell 15.

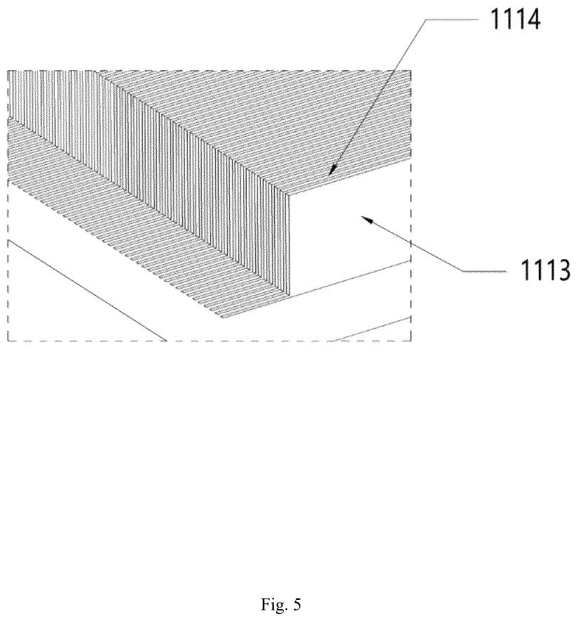

As shown in FIG. 5, the bottom cover 16 constitutes the heat conduction surface 14. A top of the bottom cover 16 is provided with a plurality of second flow guide ribs 1113, and heat exchange channels 1114 are formed between the second flow guide ribs 1113 to improve heat exchange efficiency.

As shown in FIG. 1, this embodiment is based on any of the foregoing embodiments. The housing 1 is provided with a mounting hole 17 communicating with the cavity 11, and a sensor 6 is disposed in the mounting hole 17. The sensor 6 is configured to monitor water temperature, water quality, water pressure, and liquid level within the cavity 11. The sensor 6 is connected to a controller. The controller is also connected to the drive device 3. The controller is configured to control a rotational speed of the impeller 2 according to detection data from the sensor 6. Specifically, the controller is disposed on the PCB 43. Additionally, a wireless transceiver for data transmission is also disposed on the PCB 43. This configuration enables transmission of operational data of the pump to terminals such as computers and mobile phones.

The above descriptions are only preferred embodiments of the present disclosure and are not intended to limit the patent scope of the present disclosure, and any equivalent structural transformation made by the description and drawings of the present disclosure or direct/indirect application in other related technical fields is included in the patent protection scope of the present disclosure under the inventive concept of the present disclosure.

What is claimed is:

1. A cooling assembly based on a contactless drive structure, comprising:
a housing, wherein the housing is provided with a cavity inside, an impeller is rotatably disposed in the cavity; the housing is further provided with a fluid inlet and a fluid outlet, and both the fluid inlet and the fluid outlet are in communication with the cavity; and
a drive device, wherein the drive device comprises a stator and a rotor, a pump seat is detachably disposed on an upper portion of the housing, the stator is disposed on the pump seat, the rotor is directly or indirectly connected to the impeller, and magnetic fields of the rotor and the stator are axially or radially tangent to each other; the drive device is configured to drive the impeller to rotate via the stator and the rotor, so as to drive fluid to enter the cavity from the fluid inlet, and then be discharged from the cavity via the fluid outlet;
wherein a bottom of the housing is provided with a heat conduction surface.

2. The cooling assembly based on the contactless drive structure according to claim 1, wherein a disc extending in a radial direction of the impeller is disposed on an upper portion of the impeller, and a rotor is directly or indirectly disposed on the disc.

3. The cooling assembly based on the contactless drive structure according to claim 2, wherein the rotor comprises a plurality of permanent magnets, the stator comprises a plurality of induction coils, the permanent magnets are disposed on the disc, both the permanent magnets and the induction coils are distributed along a circumferential direction of the disc, and magnetic flux directions of the induction coils and the permanent magnets are along an axial direction of the impeller.

4. The cooling assembly based on the contactless drive structure according to claim 2, wherein the rotor and the disc are integrally formed.

5. The cooling assembly based on the contactless drive structure according to claim 2, wherein a projected area of the stator and a projected area of the rotor are identical.

6. The cooling assembly based on the contactless drive structure according to claim 1, wherein a cylinder extending in the axial direction of the impeller is disposed on the impeller, a bottom of the pump seat is provided with an annular groove, the annular groove is in communication with the cavity, and the cylinder is located in the annular groove.

7. The cooling assembly based on the contactless drive structure according to claim 6, wherein the rotor comprises a plurality of permanent magnets, the stator comprises a plurality of induction coils, the permanent magnets are disposed on the cylinder, both the permanent magnets and the induction coils are distributed along a circumferential direction of the cylinder, and magnetic flux directions of the induction coils are along a radial direction of the impeller.

8. The cooling assembly based on the contactless drive structure according to claim 6, wherein the pump seat is provided with a mounting groove recessed downward, the mounting groove is located in the annular groove, and the stator is disposed in the mounting groove.

9. The cooling assembly based on the contactless drive structure according to claim 1, wherein the cavity comprises a water chamber and an impeller chamber, the impeller chamber is located above the water chamber, a partition plate is disposed between the water chamber and the impeller chamber, a plurality of first through holes are provided on the partition plate, the first through holes are in communication with water chamber and the impeller chamber, the impeller is located in the impeller chamber, the fluid inlet is in communication with the impeller chamber, and the fluid outlet is in communication with the water chamber.

10. The cooling assembly based on the contactless drive structure according to claim 9, wherein a flow guide channel is disposed in the water chamber, the flow guide channel is in communication with the first through holes, the heat conduction surface, and the fluid outlet; and
when the impeller rotates, the impeller is configured to drive fluid to pass sequentially through the fluid inlet, the impeller chamber, the flow guide channel, and the fluid outlet.

11. The cooling assembly based on the contactless drive structure according to claim 10, wherein the flow guide channel comprises a first flow guide channel, a heat exchange region, and a second flow guide channel, the heat exchange region is located at a lower portion of the water chamber, the heat exchange region is in communication with the heat conduction surface, the first flow guide channel is in communication with both the first through holes and the heat exchange region, and the second flow guide channel is in communication with both the heat exchange region and the fluid outlet.

12. The cooling assembly based on the contactless drive structure according to claim 11, wherein the water chamber is provided with a flow guide base inside, the flow guide base is provided with a second through hole and a third through hole, both the second through hole and the third through hole penetrate through the flow guide base vertically, a bottom of the flow guide base is provided with a recess, an inner area of the recess forms the heat exchange region, and both the second through hole and the third through hole are in communication with the recess; and
a top of the water chamber is provided with a plurality of first flow guide ribs, the first flow guide ribs and the first through holes form the first flow guide channel, and the third through hole and the first flow guide ribs form the second flow guide channel.

13. The cooling assembly based on the contactless drive structure according to claim 11, wherein the second flow guide channel is disposed on each of both sides of the first flow guide channel, the two second flow guide channels are connected via a connection channel, and one of the second flow guide channels is in communication with the fluid outlet.

14. The cooling assembly based on the contactless drive structure according to claim 13, wherein the water chamber is provided with a flow guide base inside, the flow guide base is provided with a second through hole and a third through hole, both the second through hole and the third through hole penetrate through the flow guide base vertically, the third through hole is disposed on each of both sides of the second through hole, a bottom of the flow guide base is provided with a recess, an inner area of the recess forms the heat exchange region, and both the second through hole and the third through hole are in communication with the recess; and
a top of the water chamber is provided with a plurality of first flow guide ribs, the first flow guide ribs and the second through hole form the first flow guide channel, the two third through holes and the first flow guide ribs form the two second flow guide channels, and the first flow guide ribs further form the connection channel.

15. The cooling assembly based on the contactless drive structure according to claim 9, wherein a bottom of the water chamber is provided with a plurality of second flow guide ribs, and heat exchange channels are formed between the second flow guide ribs.

16. The cooling assembly based on the contactless drive structure according to claim 1, wherein the housing comprises an upper shell and a bottom cover, the cavity is provided at a bottom of the upper shell, the bottom cover is configured to close the bottom of the upper shell, and the pump seat is mounted on a top of the upper shell.

17. The cooling assembly based on the contactless drive structure according to claim 16, wherein a top of the bottom cover is provided with a plurality of second flow guide ribs, and heat exchange channels are formed between the second flow guide ribs.

18. The cooling assembly based on the contactless drive structure according to claim 1, wherein a rotating shaft is rotatably disposed in the cavity, and the impeller is disposed on the rotating shaft.

19. The cooling assembly based on the contactless drive structure according to claim 1, wherein the housing is provided with a mounting hole communicating with the cavity, and a sensor is disposed in the mounting hole.
